(19) United States
(12) Patent Application Publication
(10) Pub. No.: US 2022/0271100 A1
(43) Pub. Date: Aug. 25, 2022

(54) DISPLAY PANEL AND DISPLAY DEVICE

(71) Applicant: YUNGU (GU'AN) TECHNOLOGY CO., LTD., Langfang (CN)

(72) Inventors: Zhimin YAN, Langfang (CN); Hao LI, Langfang (CN); Hung-Chi TAI, Langfang (CN); Junwei LIU, Langfang (CN)

(73) Assignee: YUNGU (GU'AN) TECHNOLOGY CO., LTD., Langfang (CN)

(21) Appl. No.: 17/740,728

(22) Filed: May 10, 2022

Related U.S. Application Data
(63) Continuation of application No. PCT/CN2021/081748, filed on Mar. 19, 2021.

(30) Foreign Application Priority Data
May 26, 2020 (CN) 202010457750.7

(51) Int. Cl. H01L 27/32; H01L 51/52

(52) U.S. Cl. CPC H01L 27/3209; H01L 27/3211; H01L 51/5271; H01L 51/5206; H01L 51/5221

(57) ABSTRACT

A display panel and a display device. The display panel includes a first electrode layer, a second electrode layer, and N light-emitting structural layers stacked between the first electrode layer and the second electrode layer; each of the light-emitting structural layers includes a plurality of light-emitting units corresponding to respective sub-pixels, the light-emitting unit includes a plurality of functional film layers arranged in a stacked manner, one of the plurality of functional film layers is a light-emitting layer; the first electrode layer and the light-emitting layers in the i-th light-emitting structural layer have a plurality of first optical lengths provided therebetween, the first optical lengths corresponding to the sub-pixels of a same color have a same value, and the first optical length has a linear relationship with a wavelength of light emitted by the light-emitting unit, i is 1, 2, 3 . . . N.

### CROSS-REFERENCE TO RELATED APPLICATIONS

This application is a continuation of International Application No. PCT/CN2021/081748, filed on Mar. 19, 2021, which claims priority to Chinese Patent Application No. 202010457750.7 filed on May 26, 2020, both of which are hereby incorporated by reference in their entireties.

### FIELD

The present application relates to the field of display, in particular to a display panel and a display device.

### BACKGROUND

With the rapid development of electronic devices, users pay more and more attention to the performance of display screens. In some use scenarios such as vehicles, TVs or the like, the lifetime of the display screens is particularly important.

In order to improve the lifetime of the display screens, stacked devices are generally used in the prior art to increase the lifetime of the devices. This is because the stacked devices theoretically need only half or less current density to reach the same brightness, while the lifetime of the devices is an exponential function of the current density. Therefore, using the stacked devices may significantly prolonged the lifetime. However, in the stacked devices, especially in top-emitting stacked devices, when the positions of two light-emitting layers deviate, the device efficiency will decrease sharply due to the microcavity effect in the top-emitting light-emitting structural layer.

Thus, a new display panel and display device are urgently needed.

### SUMMARY

The present application provides a display panel and a display device, for improving the device efficiency of a light-emitting device of the display panel.

An embodiment of the first aspect of the present application provides a display panel, comprising a first electrode layer, a second electrode layer and N light-emitting structural layers stacked between the first electrode layer and the second electrode layer, N is a positive integer, wherein each of the light-emitting structural layers has a plurality of light-emitting units corresponding to respective sub-pixels, the light-emitting unit includes a plurality of functional film layers arranged in a stacked manner, one of the functional film layers is a light-emitting layer; the first electrode layer and the light-emitting layers in the i-th light-emitting structural layer have a plurality of first optical lengths provided therebetween, i is 1, 2, 3 . . . N, and the first optical lengths corresponding to the sub-pixels of a same color have a same value, and the first optical length has a linear relationship with a wavelength of light emitted by the light-emitting unit.

An embodiment of the second aspect of the present application provides a display device, comprising the display panel of any implementation of the first aspect.

According to the embodiments of the present application, the display panel comprises a first electrode layer, N light-emitting structural layers and a second electrode layer arranged in a stacked manner, each of the light-emitting structural layers includes a plurality of light-emitting units corresponding to respective sub-pixels, and the plurality of light-emitting units are used to emit lights of different colors corresponding to the respective sub-pixels. First optical lengths corresponding to the sub-pixels of the same color have the same value, and the same reflection occurs after the lights of the same color reach the first electrode layer, which may enhance the brightness of the lights of the same color. The first optical length has a linear relationship with the wavelength of the light emitted by the light-emitting unit. Setting the first optical lengths according to the wavelengths of the lights is beneficial to the extraction of the lights, thereby enhancing the luminous effects. Therefore, the embodiments of the present application may not only enhance the brightness of the lights of the same color, but also enhance the luminous effects.

### BRIEF DESCRIPTION OF THE DRAWINGS

Other features, objects and advantages of the present application will become more apparent by reading the following detailed description of the non-limiting embodiments with reference to the accompanying drawings, in which the same or like reference numerals denote the same or like features, and the figures are not drawn to actual scale.

FIG. 1 illustrates a structural diagram of a display panel provided according to an embodiment of the present application;

FIG. 2 illustrates a structural diagram of a display panel provided according to another embodiment of the present application, and FIG. 2 shows optical lengths between different charge generating layers 400 and a first electrode layer 100;

FIG. 3 illustrates an example waveform of a light;

FIG. 4 illustrates an example waveform of another light;

FIG. 5 illustrates an example waveform of yet another light;

FIG. 6 illustrates a structural diagram of a display panel provided according to yet another embodiment of the present application, and FIG. 6 shows optical lengths between different charge generating layers 400 and the first electrode layer 100 when the display panel has two light-emitting structural layers 200;

FIG. 7 illustrates a structural diagram of the display panel in a Comparative Example 1;

FIG. 8 illustrates a spectrum chart of a blue light emitted by the display panel provided in yet another embodiment of the present application;

FIG. 9 illustrates a spectrum chart of a blue light emitted in the Comparative Example 1;

FIG. 10 illustrates a spectrum chart of a green light emitted by the display panel provided in yet another embodiment of the present application;

FIG. 11 illustrates a spectrum chart of a red light emitted by the display panel provided in yet another embodiment of the present application.

### DETAILED DESCRIPTION

The features and exemplary embodiments of various aspects of the present application will be described in detail below, in order to render the purposes, technical solutions and advantages of the present application clearer. The present application will be further described in detail below in combination with the accompanying drawings and specific embodiments. It should be understood that the specific embodiments described herein are only for illustrating the present application rather than limiting. For those skilled in the art, the present application may be implemented without some of these specific details. The following description of the embodiments is only intended to provide a better understanding of the present application by showing examples of the present application.

It should be noted herein that, relational terms such as first and second are only used to distinguish one entity or operation from another, and do not necessarily require or imply any actual relationship or order between these entities or operations. The embodiments of the application provide a display panel and a display device. The embodiments of the display panel and the display device will be described below in combination with the accompanying drawings.

The embodiments of the present application provide a display panel, which may be an organic light emitting diode (Organic Light Emitting Diode, OLED) display panel. The display panel may be an organic light emitting diode display panel with a top-emitting structure.

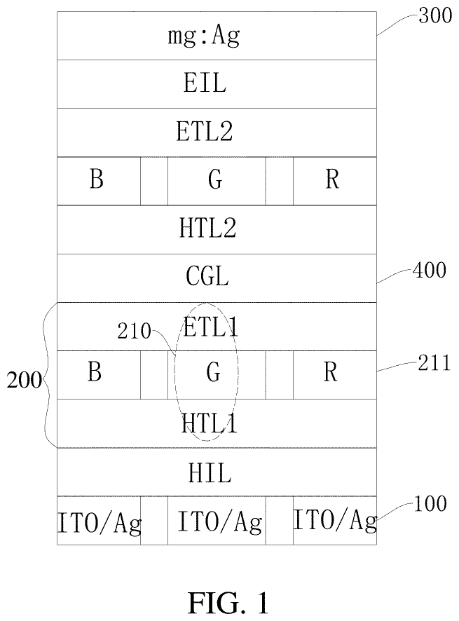

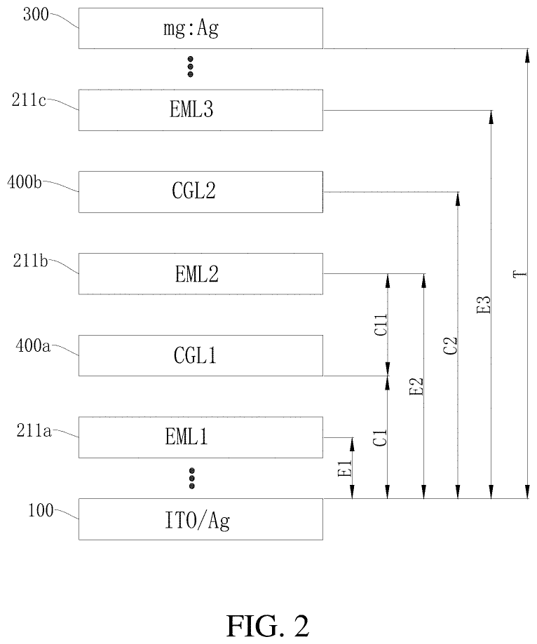

Referring to FIG. 1 and FIG. 2 together. FIG. 1 illustrates a structural diagram of a display panel provided by an embodiment of the present application, and FIG. 2 is a structural diagram of a display panel provided by another embodiment of the present application. In FIG. 2, some structures of film layers are omitted in order to better illustrate structural features of the display panel of the embodiments of the present application.

According to the embodiments of the present application, a display panel includes a first electrode layer 100, N light-emitting structural layers 200 disposed on the first electrode layer 100, and a second electrode layer 300 disposed on the light-emitting structural layers 200. That is, the display panel includes the first electrode layer 100, the second electrode layer 300 and the N light-emitting structural layers 200 stacked between the first electrode layer 100 and the second electrode layer 300, N is a positive integer, wherein each of the light-emitting structural layers includes a plurality of light-emitting units 210 corresponding to respective sub-pixels, each of the light-emitting units 210 includes a plurality of functional film layers arranged in a stacked manner, one of the plurality of functional film layers is a light-emitting layer 211; the first electrode layer 100 and the light-emitting layers 211 in the i-th light-emitting structural layer 200 have a plurality of first optical lengths provided therebetween, i is 1, 2, 3 . . . N, and the first optical lengths corresponding to the sub-pixels of a same color have a same value, and the first optical length has a linear relationship with a wavelength of light emitted by the light-emitting unit 210.

The first electrode layer 100 and the second electrode layer 300 are arranged in a variety of ways. In some alternative embodiments, the first electrode layer 100 is an anode layer, the first electrode layer 100 includes a plurality of first electrodes separated and insulated from each other. And the second electrode layer 300 is a cathode layer, which is formed by placing as a whole layer, that is, the second electrode layer 300 is a common electrode layer.

According to of the embodiments of the present application, the display panel includes the first electrode layer 100, the light-emitting structural layers 200 and the second electrode layer 300 arranged in a stacked manner, each of the light-emitting structural layers 200 includes a plurality of light-emitting units 210 corresponding to respective sub-pixels, and the plurality of light-emitting units 210 are used to emit lights of different colors corresponding to the respective sub-pixels. The values of the first optical lengths corresponding to the sub-pixels of the same color are the same, and the same reflection occurs after the lights of the same color reach the first electrode layer 100, which may enhance the brightness of the lights of the same color. The first optical length has a linear relationship with the wavelength of the light emitted by the light-emitting unit 210. Setting the first optical lengths according to the wavelengths of the lights is beneficial to the extraction of the lights, thereby enhancing the luminous effects. Therefore, the embodiments of the present application may not only enhance the brightness of the lights of the same color, but also enhance the luminous effects.

The first optical lengths may be arranged in several ways. The first electrode layer 100 has a first surface facing the light-emitting layer 211 and a second surface facing away from the light-emitting layer 211, and the light-emitting layer 211 has a third surface facing the first electrode layer 100 and a fourth surface facing away from the first electrode layer 100. The first optical length may be an optical length from the first surface, the second surface or any position between the first surface and the second surface to the third surface, the fourth surface or any position between the third surface and the fourth surface.

The sub-pixels of the display panel may be set in several ways. For example, the sub-pixels of the display panel include red sub-pixels, green sub-pixels and blue sub-pixels.

The light-emitting structural layers 200 including the light-emitting units 210 corresponding to the respective sub-pixels means that the light-emitting structural layers include the light-emitting units 210 for emitting lights with the same color as the sub-pixels. That is, the light-emitting units 210 include a plurality of red light-emitting units 210 which are corresponding to the red sub-pixels and used to emit red light, the light-emitting units 210 further include a plurality of blue light-emitting units 210 which are corresponding to the blue sub-pixels and used to emit blue light, and the light-emitting units 210 further include a plurality of green light-emitting units 210 which are corresponding to the green sub-pixels and used to emit green light.

N is a positive integer, and may be 1, 2, 3, etc. That is, one light-emitting structural layer 200 may be arranged between the first electrode layer 100 and the second electrode layer 300, or at least two light-emitting structural layers 200 may be stacked between the first electrode layer 100 and the second electrode layer 300.

The first optical lengths are optical lengths between the first electrode layer 100 and the light-emitting layers 211 in the i-th light-emitting structural layer 200. If N is 1, that is, the number of the light-emitting structural layers 200 is one, then the first optical length is an optical length between the first electrode layer 100 and the light-emitting layer 211 in the light-emitting structural layer 200.

When N is 2, 3, 4 . . . etc., that is, there are at least two light-emitting structural layers 200, the first optical length is the space between the first electrode layer 100 and the light-emitting layer 211 in one of the light-emitting structural layers 200. As shown in FIG. 2, if there are three light-emitting structural layers 200, the first optical length may be an optical length between the first electrode layer 100 and the light-emitting layer 211 in the first light-emitting structural layer 200, the first optical length may also be an optical length between the first electrode layer 100 and the light-emitting layer 211 in the second light-emitting structural layer 200, or the first optical length may also be an optical length between the first electrode layer 100 and the light-emitting layer 211 in the third light-emitting structural layer 200.

Referring to FIG. 2, the display panel includes three light-emitting structural layers 200 arranged in a stacked manner, which respectively include a first light-emitting layer 211a, a second light-emitting layer 211b and a third light-emitting layer 211c distributed in a direction from the first electrode layer 100 to the second electrode layer 300. First optical lengths E1 between the first electrode layer 100 and the first light-emitting layer 211a corresponding to sub-pixels of the same color have the same value, first optical lengths E2 between the first electrode layer 100 and the second light-emitting layer 211b corresponding to sub-pixels of the same color have the same value, and first optical lengths E3 between the first electrode layer 100 and the third light-emitting layer 211 corresponding to sub-pixels of the same color have the same value. However, the first optical lengths respectively between the first electrode layer 100 and the first light-emitting layer 211a, the second light-emitting layer 211b, the third light-emitting layer 211c are different values.

The values of the first optical lengths corresponding to sub pixels of different colors may be the same or different. In some alternative embodiments, the first optical lengths corresponding to sub pixels of different colors have different values. That is, the values of the first optical lengths corresponding to the red sub-pixels, the blue sub-pixels and the green sub-pixels are different from each other.

In these alternative embodiments, the first optical lengths corresponding to the sub pixels of different colors have different vales, so that the brightness of lights of the same color can be enhanced, and the brightness of lights of different colors will not interfere with each other.

In some alternative embodiments, the first optical length E satisfies the following relationship:

$$E = {m}_{1} \frac{λ}{4} \pm 50 Å \qquad ( 1 )$$

wherein λ is the wavelength of the light emitted by the light-emitting unit, and m₁ is a positive integer. For example, if the light-emitting unit 210 emits red light, then λ is the wavelength of red light; if the light-emitting unit 210 emits blue light, then λ is the wavelength of blue light; and if the light-emitting unit 210 emits green light, then λ is the wavelength of green light.

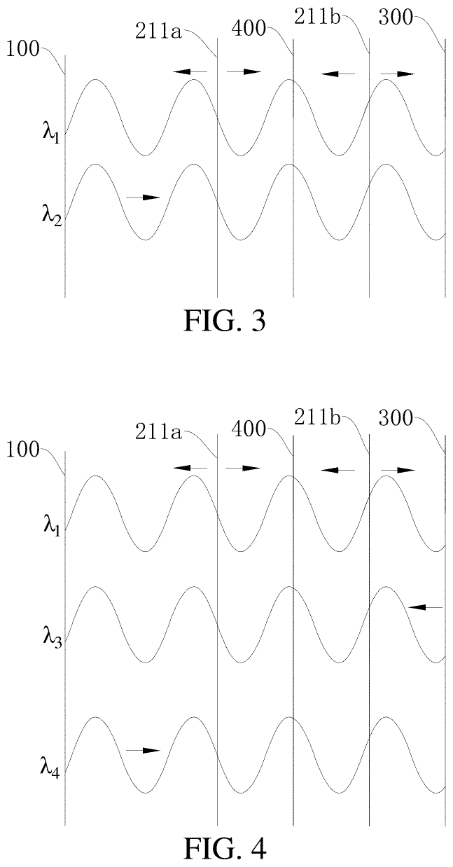

Referring to FIG. 3, the first electrode layer 100 includes a reflective material, and the lights emitted by the light-emitting layer 211 will be reflected by the first electrode layer 100. It is assumed that a first light emitted by the light-emitting layer 211 to the first electrode layer 100 forms a first waveform λ₁, and a second light reflected by the first electrode layer 100 forms a second waveform λ₂. The direction of the arrow shown in FIG. 3 indicates the propagation direction of the light. In these alternative embodiments, if the first optical length satisfies the above relationship, then the first waveform λ₁ and the second waveform λ₂ are superimposed with each other, the spaces between two adjacent wave peaks in the first waveform λ₁ and the second waveform λ₂ are small, so that the light-emitting layer 211 is at the position of constructive interference, which may enhance the light-emitting effects.

When there are at least two light-emitting layers 211 stacked with each other, if the light-emitting layers 211 are different, the values of m₁ is different when the first optical length is obtained by using equation (1), that is, since the first light-emitting layer 211a, the second light-emitting layer 211b and the third light-emitting layer 211c are different, the values of m₁ is different when the first optical length is obtained by using equation (1).

In some alternative embodiments, the values of m₁ which is in the equation (1) are the same when obtaining the first optical lengths corresponding to sub pixels of different colors in the display panel. For example, when the display panel includes a red sub-pixel, a green sub-pixel and a blue sub-pixel, the values of m₁ which is in the equation (1) are the same when obtaining the first optical lengths corresponding to the red sub-pixel, the green sub-pixel and the blue sub-pixel. Thus, the distances between the light-emitting layers 211 of different colors and the first electrode layer 100 are closer, reducing the overall thickness of the display panel.

In some alternative embodiments, the value of m₁ is less than or equal to 8. There is no specific limit on the upper limit of m₁ value. The upper limit of m₁ value can be reasonably determined by considering the overall thickness of the display panel.

As described above, two or more light-emitting structural layers 200 arranged in a stacked manner include a first light-emitting layer 211a and a second light-emitting layer 211b. In some alternative embodiments, if the sub-pixel includes a blue sub-pixel, a red sub-pixel and a green sub-pixel, the range of the first optical length E1 between the first light-emitting layer 211A corresponding to the blue sub-pixel and the first electrode layer 100 is 230 nm to 250 nm. And/or the range of the first optical length E1 between the first light-emitting layer 211A corresponding to the green sub-pixel and the first electrode layer 100 is 260 nm to 270 nm. And/or the range of the first optical length E1 between the first light-emitting layer 211a corresponding to the red sub-pixel and the first electrode layer 100 is 310 nm to 320 nm. When the range of the first optical length E1 is within the above range, the values of the first optical length E1 corresponding to sub pixels of different colors are different, so as to avoid the mutual interference of the lights of sub-pixels of different colors and improve the luminous efficiency of the display panel.

In other alternative embodiments, the range of the first optical length E2 between the second light-emitting layer 211b corresponding to the blue sub-pixel and the first electrode layer 100 is 435 nm to 485 nm. And/or, the range of the first optical length E2 between the second light-emitting layer 211b corresponding to the green sub-pixel and the first electrode layer 100 is 515 nm to 555 nm. And/or the range of the first optical length E2 between the second light-emitting layer 211b corresponding to the red sub-pixel and the first electrode layer 100 is 615 nm to 655 nm. When the range of the first optical length E2 is within the above range, the values of the first optical length E2 corresponding to sub pixels of different colors are different, so as to avoid the mutual interference of the lights of sub-pixels of different colors and improve the luminous efficiency of the display panel.

In some alternative embodiments, the thickness d of other functional films between the light-emitting layer 211 and the first electrode layer 100 and the refractive index n thereof satisfy the following relationship:

$${d}_{1} {n}_{1} + {d}_{2} {n}_{2} + … + {d}_{q} {n}_{q} = {m}_{1} \frac{λ}{4} \pm 50 Å \qquad ( 2 )$$

Wherein d_{q} is the thickness of the q-th functional film and n_{q} is the refractive index of the q-th functional film.

In these alternative embodiments, the thickness of the functional film between the first electrode layer 100 and the light-emitting layer 211 can be reasonably set according to the first optical length, in order to further improve the light-emitting efficiency of the display panel.

In some alternative embodiments, the first electrode layer 100 and the second electrode layer 300 have a plurality of second optical lengths provided therebetween, the second optical lengths corresponding to the sub-pixels of the same color have the same value, and the second optical length has a linear relationship with the wavelength of the light emitted by the light-emitting unit 210.

In these alternative embodiments, the first electrode layer 100 and the second electrode layer 300 generally include a reflective material, the second electrode layer 300 is generally referred to as a semi-reflective layer, and the second electrode layer 300 reflects the light emitted by the light-emitting layer 211 and the light reflected by the first electrode layer 100. The second optical length between the first electrode layer 100 and the second electrode layer 300 corresponds to the sub-pixels of a same color are same, so that the optical lengths of the lights which are between the first electrode layer 100 and the second electrode layer 300 and emitted by the light-emitting units 210 corresponding to the sub-pixels of the same color are the same, which can further improve the brightness of the light of the same color. The second optical length has a linear relationship with the wavelength of the light emitted by the light-emitting unit 210, which is beneficial to the extraction of the lights.

The second optical length may be set in various ways. For example, the second electrode layer 300 includes a fifth surface facing the first electrode layer 100 and a sixth surface facing away from the first electrode layer 100. The second optical length may be an optical length from the first surface, the second surface, or any position between the first surface and the second surface to the fifth surface, the sixth surface, or any position between the fifth surface and the sixth surface.

The values of the second optical lengths corresponding to the sub-pixels of the same color are the same means that: the second optical lengths corresponding to the sub-pixels of the same color are the same, that is, the second optical lengths corresponding to a plurality of red sub-pixels in the display panel are the same, the second optical length corresponding to a plurality of blue sub-pixels are the same, and the second optical lengths corresponding to a plurality of green sub-pixels are the same.

The values of the second optical length corresponding to sub pixels of different color may be the same or different. In some alternative embodiments, the second optical lengths corresponding to sub pixels of different colors have different values. That is, the value of the second optical length corresponding to the red sub-pixel, the value of the second optical length corresponding to the blue sub-pixel and the value of the second optical length corresponding to the green sub-pixel are different from each other.

In these alternative embodiments, the second optical lengths corresponding to sub-pixels of different colors have different values, so that the brightness of lights of the same color can be enhanced, and the brightness of lights of different colors will not interfere with each other.

In some alternative embodiments, the second optical length T satisfies the following relationship:

$$T = ( 2 {m}_{2} - 1 ) \frac{λ}{4} \pm 100 Å \qquad ( 3 )$$

Wherein, λ is the wavelength of the light emitted by the light-emitting unit 210, and m₂ is a positive integer. For example, if the light-emitting unit 210 emits red light, λ is the wavelength of red light; if the light-emitting unit 210 emits blue light, λ is the wavelength of blue light; if the light-emitting unit 210 emits green light, λ is the wavelength of green light.

Referring to FIG. 4, the first electrode layer 100 and the second electrode layer 300 generally include a reflective material. It is assumed that the second electrode layer 300 reflects the above first light to form a third light, and the third light has a third waveform λ₃. The first electrode layer 100 reflects the third light to form a fourth light, and the fourth light has a fourth waveform λ₄. The arrow shown in FIG. 4 indicates the propagation direction of light. In these alternative embodiments, the second optical length satisfies the above relationship so that the third waveform λ₃ and the first waveform λ₁ can be superimposed with each other, that is, the distance between two adjacent peaks in the third waveform λ₃ and the first waveform λ₁ is small, which may enhance the effect of light. At the same time, the third waveform λ₃ and the fourth waveform λ₄ can be superimposed with each other, that is, the distance between two adjacent peaks in the third waveform λ₃ and the fourth waveform λ₄ is small, which may enhance the effect of light and is beneficial to the extraction of the lights.

In some alternative embodiments, the values of m₂ which is in the equation (3) are the same when obtaining the second optical lengths corresponding to sub pixels of different colors in the display panel. For example, when the display panel includes a red sub-pixel, a green sub-pixel and a blue sub-pixel, the values of m₂ which is in the equation (3) are the same when obtaining the second optical lengths corresponding to the red sub-pixel, the green sub-pixel and the blue sub-pixel. Thus, the light-emitting layers 211 of different colors are closer to the first electrode layer 100, reducing the overall thickness of the display panel.

In some alternative embodiments, the value of m₂ is less than or equal to 8. There is no specific limit on the upper limit of m₂ value. The upper limit of m₂ value can be reasonably determined by considering the overall thickness of the display panel.

In some alternative embodiments, the second optical length corresponding to the blue sub-pixel ranges from 560 nm to 590 nm, and/or the second optical length corresponding to the green sub-pixel ranges from 650 nm to 680 nm, and/or the second optical length corresponding to the red sub-pixel ranges from 770 nm to 800 nm.

In some alternative embodiments, the thickness d of other functional film layers between the second electrode layer 300 and the first electrode layer 100 and the refractive index n thereof satisfy the following relationship:

$${d}_{1} {n}_{1} + {d}_{2} {n}_{2} + … + {d}_{p} {n}_{p} = ( 2 {m}_{2} - 1 ) \frac{λ}{4} \pm 100 Å \qquad ( 4 )$$

Wherein dₚ is the thickness of the p-th functional film and nₚ is the refractive index of the p-th functional film.

In these alternative embodiments, the thickness of the functional film layer between the first electrode layer 100 and the second electrode layer 300 may be reasonably set according to the second optical length, so as to further improve the luminous efficiency of the display panel.

In some alternative embodiments, in order to improve the lifetime of the display panel, at least two light-emitting structural layers 200 are arranged in a stacked manner, and a charge generating layer 400 is arranged between the stacked light-emitting structural layers 200; W charge generating layers 400 are stacked between the first electrode layer 100 and the second electrode layer 300, W is a positive integer, there is a third optical length between the first electrode layer 100 and the j-th charge generating layer 400, the third optical lengths corresponding to sub-pixels of the same color have the same value, and the third optical length has a linear relationship with the wavelength of the light emitted by the light-emitting unit 210, j is 1, 2, 3 . . . W.

In these alternative embodiments, the charge generating layer 400 generally includes a reflective material, and the charge generating layer 400 reflects the light emitted by the light-emitting layers 211 and the light reflected by the first electrode layer 100. The third optical lengths corresponding to the sub-pixels of the same color have the same value, so that the optical lengths of the lights which are between the charge generating layer 400 and the first electrode layer 100 and emitted by the light-emitting units 210 corresponding to the sub-pixels of the same color are the same, which can further improve the brightness of the lights of the same color. The third optical length has a linear relationship with the wavelength of the light emitted by the light-emitting unit 210, which is beneficial to the extraction of the lights.

The third optical length may be set in several ways. For example, the charge generating layer 400 includes a seventh surface facing the first electrode layer 100 and an eighth surface facing away from the first electrode layer 100. The third optical length may be an optical length from the first surface, the second surface, or any position between the first surface and the second surface to the seventh surface, the eighth surface, or any position between the seventh surface and the eighth surface.

The number of charge generating layers 400 is not particularly limited. For example, if only two light-emitting structural layers 200 are stacked with each other, the value of W is 1 and the number of the charge generating layers 400 is one. If at least three light-emitting structural layers 200 are stacked with each other, W is a positive integer, W is greater than or equal to 2, and the number of the charge generating layers 400 may be two or more.

In some alternative embodiments, when two charge generating layers 400 are arranged in a stacked manner, there is a third optical length between the first electrode layer 100 and the j-th charge generating layer 400, and the value of j may be 1, 2, 3 . . . W. That is, the third optical length may be an optical length between the first charge generating layer 400 and the first electrode layer 100, or the third optical length may be an optical length between the second charge generating layer 400 and the first electrode layer 100.

The optical lengths between different charge generating layers 400 and the first electrode layer 100 are different. As shown in FIG. 2, there are two charge generating layers 400 arranged in a stacked manner, the two charge generating layers 400 are the first charge generating layer 400a and the second charge generating layer 400b respectively, and the third optical length between the first charge generating layer 400a and the first electrode layer 100 is C1, and the third optical length between the second charge generating layer 400b and the first electrode layer 100 is C2, and the values of C1 and C2 are different.

The third optical lengths corresponding to sub-pixels of the same color have the same value, which means that the values of the third optical lengths corresponding to the sub-pixel of the same color are the same, that is, the values of the third optical lengths corresponding to a plurality of red sub-pixels in the display panel are the same, the values of the third optical lengths corresponding to a plurality of blue sub-pixels are the same, and the values of the third optical lengths corresponding to a plurality of green sub-pixels are the same.

The values of the third optical lengths corresponding to sub pixels of different colors may be the same or different. In some alternative embodiments, the third optical lengths corresponding to the sub pixels of different colors have different values. That is, the values of the third optical lengths corresponding to the red sub-pixel, the blue sub-pixel and the green sub-pixel are different from each other.

In these alternative embodiments, the values of the third optical lengths corresponding to sub pixels of different colors are different, so that the brightness of the lights of the same color can be enhanced, and the brightness of the lights of different colors will not interfere with each other.

In some alternative embodiments, the third optical lengths C between the charge generating layer 400 and the first electrode layer 100 satisfy the following relationship:

$$C = ( \frac{1}{4} + \frac{1}{2} {m}_{3} ) λ \pm 50 Å \qquad ( 5 )$$

wherein λ is the wavelength of the light emitted by the light-emitting unit 210, and m₃ is a positive integer. For example, if the light-emitting unit 210 emits red light, λ is the wavelength of red light; if the light-emitting unit 210 emits blue light, λ is the wavelength of blue light; and if the light-emitting unit 210 emits green light, λ is the wavelength of green light.

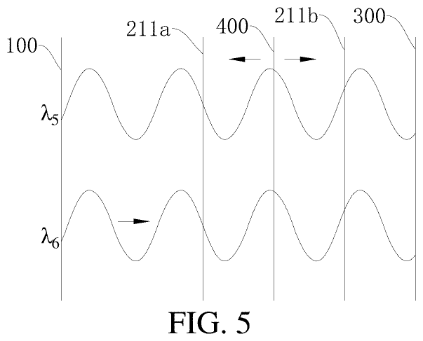

Referring to FIG. 5, the charge generating layer 400 and the first electrode layer 100 generally include a reflective material. It is assumed that the charge generating layer 400 reflects the first light to form a fifth light, and the fifth light has a fifth waveform λ₅. The first electrode layer 100 reflects the fifth light to form a sixth light, and the sixth light has a sixth waveform λ₆. The arrow shown in FIG. 5 indicates the propagation direction of the lights. In these alternative embodiments, the third optical lengths satisfy the above relationship so that the fifth waveform λ₅ and the sixth waveform λ₆ can be superimposed with each other, that is, the distance between two adjacent peaks in the fifth waveform λ₅ and sixth waveform λ₆ is small, which can weaken the microcavity effect and enhance the light effect, and further improve the efficiency of light extraction.

When there are at least two charge generating layers 400 arranged in a stacked manner, the values of m₃ which is in the equation (5) are different when obtaining the third optical length corresponding to different charge generating layers 400.

In some alternative embodiments, the values of m₃ which is in the equation (5) are the same when obtaining the third optical lengths corresponding to sub pixels of different colors in the display panel. For example, when the display panel includes a red sub-pixel, a green sub-pixel and a blue sub-pixel, the values of m₃ which is in the equation (5) are the same when obtaining the third optical lengths corresponding to the red sub-pixel, the green sub-pixel and the blue sub-pixel. Thus, the distance between the light-emitting layers 211 of different colors and the first electrode layer 100 is closer, which is beneficial to the overall thickness of the display panel.

In some alternative embodiments, the value of m₃ is less than or equal to 8. There is no specific limit on the upper limit of m₃ value. The upper limit of m₃ value can be reasonably determined by considering the overall thickness of the display panel.

In some alternative embodiments, the minimum value range of the third optical length corresponding to the blue sub-pixel is 335 nm to 355 nm. And/or, the minimum value range of the third optical length corresponding to the green sub-pixel is 390 nm to 410 nm. And/or, the minimum value range of the third optical length corresponding to the red sub-pixel is 460 nm to 470 nm.

In these alternative embodiments, if there are at least two charge generating layers 400 arranged in a stacked manner, the third optical length from the charge generating layer 400 closest to the first electrode layer 100 to the first electrode layer 100 is the smallest. That is, the third optical length C1 from the first charge generating layer 400a to the first electrode layer 100 is the smallest.

Assuming that there is a fourth optical length C11 between the first charge generating layer 400a and the second light-emitting layer 211b. In some alternative embodiments, the value range of the fourth optical length C11 corresponding to the blue sub-pixel is 100 nm to 130 nm. And/or, the value range of the fourth optical length C11 corresponding to the green sub-pixel is 125 nm to 145 nm. And/or, the value range of the fourth optical length C11 corresponding to the red sub-pixel is 155 nm to 185 nm.

In the above embodiments, the values of m₁, m₂ and m₃ may be the same or different as long as the first optical length E, the second optical length T and the third optical length C satisfy the above relationship.

In some alternative embodiments, the thickness d of the functional film layer between the first electrode layer 100 and the charge generating layer 400 and the refractive index n thereof satisfy the following relationship:

$${d}_{1} {n}_{1} + {d}_{2} {n}_{2} + … + {d}_{f} {n}_{f} = ( \frac{1}{4} + \frac{1}{2} {m}_{3} ) λ + 50 Å \qquad ( 6 )$$

Wherein d_{f} is the thickness of the f-th functional film and of is the refractive index of the f-th functional film.

In these alternative embodiments, the thickness of the functional film layer between the charge generating layer 400 and the first electrode layer 100 can be reasonably set according to the third optical length, so as to further improve the luminous efficiency of the display panel.

In the embodiments of the present application, since reasonably setting the first optical length and/or the second optical length and/or the third optical length can effectively improve the efficiency of light extraction, when a plurality of light-emitting structural layers 200 are stacked to form a stacked device, the device efficiency will not be reduced sharply, and the lifetime of the display panel can be improved while ensuring the light-emitting efficiency of the device.

In some alternative embodiments, the display panel may also include a substrate and a device layer, and the device layer is located on the substrate. One of the first electrode layer 100 and the second electrode layer 300 is an anode and the other is a cathode. The embodiments of the present application take the first electrode layer 100 as an anode for illustration. When the first electrode layer 100 is an anode, the first electrode layer 100 is located on the device layer, the light-emitting structural layers 200 is located on the first electrode layer 100, and the second electrode layer 300 is located on the light-emitting structural layers 200.

The substrate can be made of transparent materials such as glass and polyimide (Polyimide, PI). The device layer may include a pixel circuit for driving each sub-pixel to display.

In some embodiments, the first electrode layer 100 is a reflective electrode, including a first light-transmitting conductive layer, a reflective layer located on the first light-transmitting conductive layer, and a second light-transmitting conductive layer located on the reflective layer. The first light-transmitting conductive layer and the second light-transmitting conductive layer may be ITO, indium zinc oxide, etc., and the reflective layer may be a metal layer, such as silver.

In some embodiments, the second electrode layer 300 includes a magnesium silver alloy layer. In some embodiments, the second electrode layer 300 may be a common electrode.

In some embodiments, the light-emitting unit 210 may also include an electron injection layer and an electron exchanging layer located between the light-emitting layer 211 and the second electrode layer 300, and the light-emitting unit 210 may also include a hole injection layer and a hole transporting layer located between the light-emitting layer 211 and the first electrode layer 100.

For example, the display panel may also include a packaging layer, and a polarizer and a cover plate located above the packaging layer, or a cover plate directly arranged above the packaging layer without setting a polarizer.

### EMBODIMENTS

The following embodiments specifically describe the contents disclosed in the present application. These embodiments are only for illustrative description, because it is obvious to those skilled in the art to make various modifications and changes within the scope of the disclosure of the present application.

### Embodiment 1

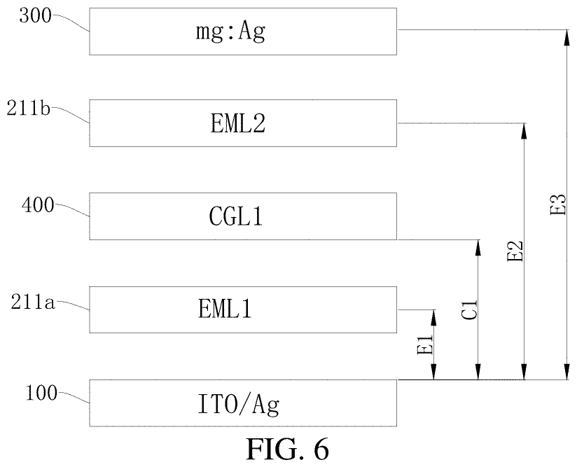

Referring to FIG. 6, the display panel includes two light-emitting structural layers 200 arranged in a stacked manner, and a charge generating layer 400 is arranged between the two light-emitting structural layers 200. The two light-emitting structural layers 200 include two light-emitting layers 211, which are a first light-emitting layer 211a and a second light-emitting layer 211b, respectively.

In the display panel shown in embodiment 1, the first optical length, the second optical length and the third optical length in the display panel are constructed according to equations (1), (3) and (5) above.

The value of m₁ which is in the equations (1) is 2 when obtaining the first optical length E1 between the first electrode layer 100 and the first light-emitting layer 211a, that is, the first optical length E1 between the first electrode layer 100 and the first light-emitting layer 211a is λ/2. The value of m₁ which is in the equations (1) is 4 when obtaining the first optical length E2 between the first electrode layer 100 and the second light-emitting layer 211b, that is, the first optical length E2 between the first electrode layer 100 and the second light-emitting layer 211b is λ The value of m₃ which is in the equations (5) is 1 when obtaining the third optical length C between the charge generating layer 400 and the first light-emitting layer 211a, that is, the third optical length C between the charge generating layer 400 and the first light-emitting layer 211A is 3λ/4. The value of m₂ which is in the equations (3) is 3 when obtaining the second optical length T between the second electrode layer 300 and the first electrode layer 100, that is, the second optical length T between the second electrode layer 300 and the first electrode layer 100 is 5λ/4.

### Comparative Example 1

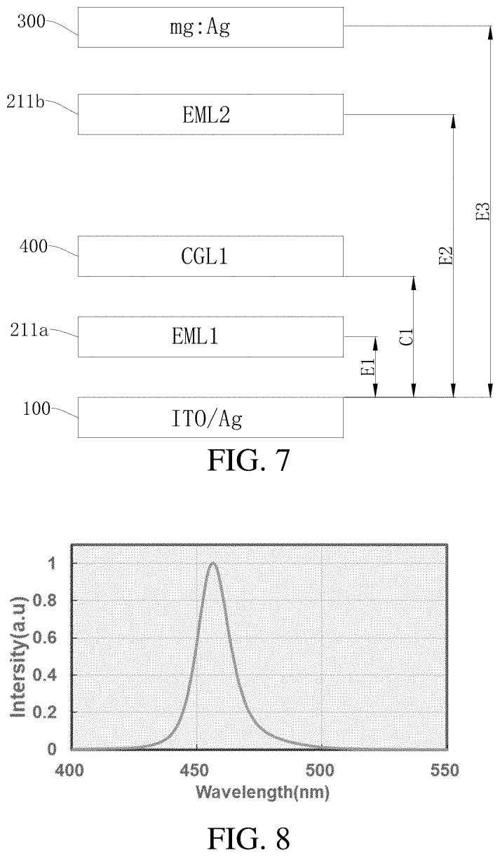

Referring to FIG. 7, the display panel in Comparative Example 1 has the same layer structure as the display panel in Embodiment 1, except that the first optical length E1 between the second light-emitting layer 211b and the first electrode layer 100 is 5λ/4, and the second optical length E2 between the first electrode layer 100 and the second electrode layer 300 is 3λ/2 in Comparative Example 1.

### Test Part of Embodiment 1 and Comparative Example 1

Let Embodiment 1 and Comparative Example 1 both emit blue light and are at the same brightness, the parameters in Embodiment 1 and Comparative Example 1 are obtained as follows:

| | | Current | Power | | | | | |
|---|---|---|---|---|---|---|---|---|
| | Voltage | Efficiency | Efficiency | | | Main | | |
| | (V) | (cd/A) | (W/lm) | CIE-x | CIE-y | peak | FWHM | BI |
| Embodiment 1 | 8.18 | 10.70 | 4.11 | 0.144 | 0.038 | 458 | 15 | 284.57 |
| Comparative | 8.96 | 12.72 | 4.46 | 0.138 | 0.245 | 452 | 39 | 51.87 |
| Example 1 | | | | | | | | |

Wherein, CIE-x and CIE-y are the positions of the blue light emitted in Embodiment 1 and Comparative Example 2 in the color coordinate diagram; Main peak is the position of the wave peak; FWHM is the half peak width; BI is the blue index.

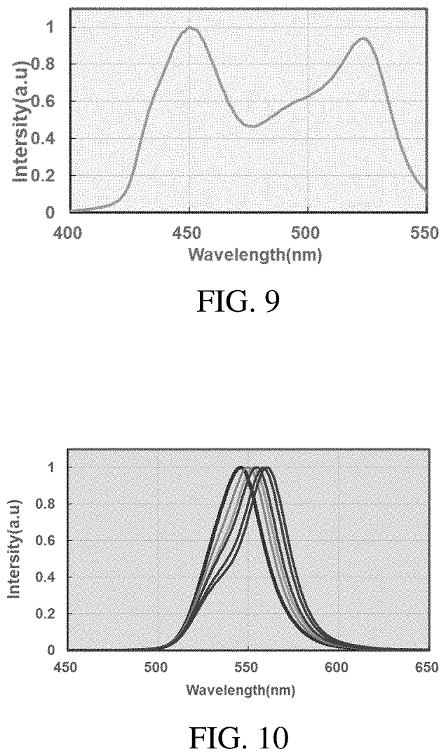

Please refer to FIG. 8 and FIG. 9 together. FIG. 8 illustrates the spectrum of the blue light emitted by the second electrode layer 300 in Embodiment 1. The abscissa of FIG. 8 is the wavelength of the emitted light and the ordinate is the normalized luminescence intensity. FIG. 9 illustrates the spectrum of blue light emitted from the second electrode layer 300 in Comparative Example 1.

According to the above table and FIG. 8 and FIG. 9, Embodiment 1 has an emission peak, the half peak width is narrow, the voltage decreases, and the luminous efficiency is increased by 5.57 times.

### Embodiment 2

In Embodiment 1, the position of the second light-emitting layer 211b is gradually changed based on the layer structure of the display panel, so that the first optical length between the second light-emitting layer 211b and the first electrode layer 100 is gradually deviated. Let the display panel in Embodiment 1 emits green light, and the obtained parameters are shown in the following table:

| | | Current | Power | | | | |
|---|---|---|---|---|---|---|---|
| | Voltage | Efficiency | Efficiency | | | Main | |
| | (V) | (cd/A) | (W/lm) | CIE-x | CIE-y | peak | FWHM |
| THK | 7.15 | 238.99 | 104.97 | 0.293 | 0.688 | 545 | 34 |
| THK + 20 Å | 7.23 | 229.37 | 99.72 | 0.311 | 0.673 | 550 | 36 |
| THK + 40 Å | 7.28 | 222.93 | 96.28 | 0.324 | 0.661 | 552 | 35 |
| THK + 60 Å | 7.24 | 198.24 | 86.08 | 0.332 | 0.654 | 554 | 36 |
| THK + 80 Å | 7.28 | 188.86 | 188.86 | 0.351 | 0.637 | 558 | 34 |
| THK + 100 Å | 7.26 | 182.08 | 78.78 | 0.363 | 0.626 | 560 | 32 |

Wherein THK is the spacing between the second light-emitting layer 211b and the first electrode layer 100 when the optical length between the second light-emitting layer 211b and the first electrode layer 100 is λ.

Referring to FIG. 10, the position of the second light-emitting layer 211b is set according to the above table, and the spectrum of the green light emitted by the second electrode layer 300 is obtained. The spectrum of the green light is obtained, as shown in FIG. 10. The abscissa of FIG. 10 is the wavelength of the emitted light and the ordinate is the normalized luminescence intensity. According to the above table and FIG. 10, when the position of the second light-emitting layer 211b gradually deviates, the peak position of the green light redshifts, the color coordinate deviates significantly, and the current efficiency decreases from 238.99 cd/A to 182.08 cd/A.

### Embodiment 3

Let the display panel in Embodiment 1 emit red light and make the display panel under the target brightness, and obtain the parameters in embodiment 1, as shown in the following table.

| | | Current | Power | | | | | |
|---|---|---|---|---|---|---|---|---|
| | Voltage | Efficiency | Efficiency | | | Main | | Voltage |
| | (V) | (cd/A) | (W/lm) | CIE-x | CIE-y | peak | FWHM | (V) |
| Embodiment 3 | 7.17 | 82.95 | 36.34 | 0.675 | 0.324 | 616 | 31 | 7.17 |

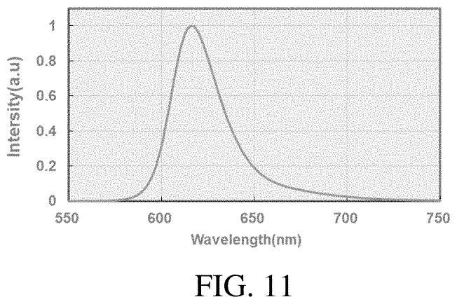

Referring to FIG. 11, the spectrum of the red light emitted by the second electrode layer 300 of the display panel is obtained, and the spectrum of the red light is obtained as shown in FIG. 11. The abscissa of FIG. 11 is the wavelength of the emitted light and the ordinate is the normalized luminescence intensity. It can be seen from FIG. 11 and the above table that the red light has a single peak and the current efficiency is 82.95 cd/A.

It can be seen from the above embodiments and test results that the embodiments of the application can not only enhance the brightness of the lights of the same color, but also enhance the luminous effect.

The embodiments of the application also provide a display device, which may include a display panel according to any of the above embodiments. Since the display device includes the above display panel, the display device of the embodiments of the present application has the beneficial effect of the above display panel, which will not be repeated here.

Those skilled in the art should understand that the above embodiments are illustrative rather than limiting. Different technical features shown in different embodiments can be combined to achieve beneficial effects. Those skilled in the art should be able to understand and realize other changed embodiments of the disclosed embodiments on the basis of studying the drawings, specification and claims. Any reference numerals in the claims shall not be construed as limiting the scope of protection. The functions of the plurality of parts described in the claims can be realized by a single hardware or software module. The appearance of some technical features in different dependent claims does not mean that these technical features cannot be combined to achieve beneficial effects.

What is claimed is:

1. A display panel comprising:
a first electrode layer, a second electrode layer and N light-emitting structural layers stacked between the first electrode layer and the second electrode layer, N is a positive integer, wherein,
each of the light-emitting structural layers comprises a plurality of light-emitting units corresponding to respective sub-pixels, the light-emitting unit comprises a plurality of functional film layers arranged in a stacked manner, one of the plurality of functional film layers is a light-emitting layer;
the first electrode layer and the light-emitting layers in the i-th light-emitting structural layer have a plurality of first optical lengths provided therebetween, i is 1, 2, 3 . . . N, and the first optical lengths corresponding to the sub-pixels of a same color have a same value, and the first optical length has a linear relationship with a wavelength of light emitted by the light-emitting unit.

2. The display panel of claim 1, wherein the first optical lengths corresponding to the sub-pixels of different colors have different values.

3. The display panel of claim 2, wherein the first optical length E satisfies the following relationship:
$$E = {m}_{1} \frac{λ}{4} \pm 50 Å$$
wherein λ is the wavelength of the light emitted by the light-emitting unit, and m₁ is a positive integer.

4. The display panel of claim 3, wherein at least two light-emitting structural layers are arranged in a stacked manner, and the light-emitting layers in the at least two light-emitting structural layers comprise a first light-emitting layer and a second light-emitting layer distributed in a direction from the first electrode layer to the second electrode layer.

5. The display panel of claim 4, wherein,
the first optical length between the first light-emitting layer corresponding to a blue sub-pixel and the first electrode layer ranges from 230 nm to 250 nm; and/or,
the first optical length between the second light-emitting layer corresponding to a blue sub-pixel and the first electrode layer ranges from 435 nm to 485 nm.

6. The display panel of claim 4, wherein,
the first optical length between the first light-emitting layer corresponding to a green sub-pixel and the first electrode layer ranges from 260 nm to 270 nm; and/or,
the first optical length between the second light-emitting layer corresponding to a green sub-pixel and the first electrode layer ranges from 515 nm to 555 nm.

7. The display panel of claim 4, wherein,
the first optical length between the first light-emitting layer corresponding to a red sub-pixel and the first electrode layer ranges from 310 nm to 320 nm; and/or
the first optical length between the second light-emitting layer corresponding to a red sub-pixel and the first electrode layer ranges from 615 nm to 655 nm.

8. The display panel of claim 3, wherein a thickness d of each of the other functional film layers, located between the light-emitting layer and the first electrode layer, and a refractive index n thereof satisfies the following relationship:
$${d}_{1} {n}_{1} + {d}_{2} {n}_{2} + … + {d}_{q} {n}_{q} = {m}_{1} \frac{λ}{4} \pm 50 Å$$
wherein d_{q} is the thickness of the q-th functional film layer, and n_{q} is the refractive index of the q-th functional film layer.

9. The display panel of claim 1, wherein the first electrode layer and the second electrode layer have a plurality of second optical lengths provided therebetween, the second optical lengths corresponding the sub-pixels of a same color have a same value, and the second optical length has a linear relationship with the wavelength of the light emitted by the light-emitting unit.

10. The display panel of claim 9, wherein the second optical lengths corresponding to the sub pixels of different colors have different values.

11. The display panel of claim 10, wherein the second optical length T satisfies the following relationship:
$$T = ( 2 {m}_{2} - 1 ) \frac{λ}{4} \pm 100 Å$$
wherein λ is the wavelength of the light emitted by the light-emitting unit, and m₂ is a positive integer.

12. The display panel of claim 11, wherein,
the second optical length corresponding to a blue sub-pixel ranges from 560 nm to 590 nm; and/or,
the second optical length corresponding to a green sub-pixel ranges from 650 nm to 680 nm.

13. The display panel of claim 11, wherein the second optical length corresponding to a red sub-pixel ranges from 770 nm to 800 nm.

14. The display panel of claim 11, wherein a thickness d of each functional film layer, located between the first electrode layer and the second electrode layer, and a refractive index n thereof satisfies the following relationship:
$${d}_{1} {n}_{1} + {d}_{2} {n}_{2} + … + {d}_{p} {n}_{p} = ( 2 {m}_{2} - 1 ) \frac{λ}{4} \pm 100 Å$$
wherein dₚ is the thickness of the p-th functional film layer, and nₚ is the refractive index of the p-th functional film layer.

15. The display panel of claim 1, wherein at least two light-emitting structural layers are arranged in a stacked manner, and at least one charge generating layer is arranged between two adjacent light-emitting structural layers which are stacked;
wherein W charge generating layers are stacked between the first electrode layer and the second electrode layer, W is a positive integer, a plurality of third optical lengths are provided between the first electrode layer and the j-th charge generating layer, the third optical lengths corresponding to the sub-pixels of a same color have a same value, and the third optical length has a linear relationship with the wavelength of the light emitted by the light-emitting unit, j is 1, 2, 3 . . . W.

16. The display panel of claim 15, wherein the third optical lengths corresponding to the sub-pixels of different colors have different values.

17. The display panel of claim 16, wherein the third optical length C between the charge generating layer and the first electrode layer satisfies the following relationship:
$$C = ( \frac{1}{4} + \frac{1}{2} {m}_{3} ) λ \pm 50 Å$$
wherein λ is the wavelength of the light emitted by the light-emitting unit, and m₃ is a positive integer.

18. The display panel of claim 17, wherein,
the minimum value range of the third optical length corresponding to a blue sub-pixel is 335 nm to 355 nm;
the minimum value range of the third optical length corresponding to a green sub-pixel is 390 nm to 410 nm;
the minimum value range of the third optical length corresponding to a red sub-pixel is 460 nm to 470 nm.

19. The display panel of claim 17, wherein a thickness d of each functional film layer, located between the first electrode layer and the charge generating layer, and a refractive index n thereof satisfies the following relationship:
$${d}_{1} {n}_{1} + {d}_{2} {n}_{2} + … + {d}_{f} {n}_{f} = ( \frac{1}{4} + \frac{1}{2} {m}_{3} ) λ + 50 Å$$
wherein d_{f} is the thickness of the f-th functional film layer, and n_{f} is the refractive index of the f-th functional film layer.

20. A display device comprising the display panel of claim 1.
